(19) United States
(12) Patent Application Publication
(10) Pub. No.: US 2009/0047538 A1
(43) Pub. Date: Feb. 19, 2009

(54) Method for Production of a Bead Single Crystal

(76) Inventors: Bert Voigtlaender, Juelich (DE); Udo Linke, Dueren (DE); Helmut Stollwerk, Juelich (DE)

Correspondence Address: JORDAN AND HAMBURG LLP, 122 EAST 42ND STREET, SUITE 4000, NEW YORK, NY, 10168, US

(21) Appl. No.: 11/988,521

(22) PCT Filed: Jul. 5, 2006
(86) PCT No.: PCT/DE2006/001159

§ 371 Date: Feb. 26, 2008

(30) Foreign Application Priority Data
Jul. 11, 2005 (DE) 10 2005 032 594.7

(51) Int. Cl. C22C 5/00; C30B 13/00

(52) U.S. Cl. 428/546; 117/37; 420/580

(57) ABSTRACT

A method for production of a bead single crystal includes heating at least one wire using electron beam heating to form the bead single crystal. The bead single crystal is advantageously produced by the electron beam heating of the at least one wire in vacuo. Bead single crystals comprising Ag, Al, Cr, Cu, Ir, Mo, Nb, Ni, Pd, Pt, Re, Rh, Ru, Ta, W or metal alloys, in particular, Ag/Au, Pt/Rh or Pt/Re alloys are advantageously produced by the method. The bead single crystals are preferably used in surface research, thin layer technology and electrochemistry.

### BACKGROUND OF THE INVENTION

The invention relates to a method for producing a bead single crystal.

Bead single crystals occur when a thin wire that comprises a noble metal is melted and recrystallized. The end of the wire is melted with a fine gas flame. A liquid metal bead forms when the gas flame is moved along the wire axis. A growth nucleus forms on the interface between the molten bead and the wire. A single crystal forms on this nucleus when the liquid ball of material hardens. In accordance with J. Clavilier et al. (J. Eletroanal. Chem. 107 (1980), 211) this method for producing bead single crystals is also known as the flame melting (FM) method.

Known from DE 103 04 533 is another method for producing a bead single crystal in which at least two wires are melted together using the flame melting method.

Another method for producing single-crystal Pt crystals is known from Furuya et al. (Furuya, N., Ichinose, M., Shibita, M. (2001), Production of high quality Pt single crystals using a new flame float-zone method. Phys. Chem. Chem. Phys. 3, 3255-3260). A Pt wire is melted in the center of the wire, also by means of an oxygen-rich hydrogen flame, and the molten zone is moved to the end of the wire. This method is also called the flame float zone (FFZ) method.

It is a disadvantage of these methods in the prior art that it is only possible to produce small bead single crystals from noble metals such as e.g. Pt and Au.

In particular for electrochemical or sensor applications a crystallographically precisely defined surface of the crystal is also desired that cannot be obtained with any of the aforesaid methods.

It is the object of the invention to provide a method for producing a bead single crystal with which a crystalographically precisely defined surface of the bead single crystal can be produced. It should also be possible to use wires made of non-noble metals.

### SUMMARY OF THE INVENTION

The object is attained using a method in accordance with

The method for producing a bead single crystal provides, in accordance with the invention, that the bead single crystal is formed using electron beam heating of at least one wire.

After formation of the of the bead single crystal, the quality of the crystal is determined using the periodicity of the modules on the facets under the stereoscopic microscope.

The bead single crystals formed by electron beam heating regularly have a precisely defined surface and thus a particularly uniform, homogeneous crystal lattice. It is particularly advantageous that the single crystals formed in this manner also have a much smaller dislocation density than the single crystals known from the prior art.

In the framework of the invention it was found that the flame melting methods in accordance with the prior art exert a pressure on the bead single crystal that is forming. Dislocations in the crystal are produced by the vibrations that occur therein. In addition, there is even the risk that the bead single crystal will crack open.

A bead single crystal that has a much smaller dislocation density and thus particularly high quality in terms of orientation can thus be produced by means of electron beam heating in a particularly advantageous manner.

In the framework of the invention it was also found that it is not possible to prevent gas diffusion from the flame into the bead single crystal by means of the methods in accordance with the prior art. Particularly affected thereby are so-called getter materials such as e.g. Va, Ta, and Pd. However, for each wire made of a non-noble metal, such as e.g. a wire made of Cu or Ni, in fact it is oxidized by means of the flame melting method according to Clavilier or even Furuya et al. Therefore the quality of the bead single crystal using the flame melting method or even the so-called flame float zone (FFZ) method is, in general, limited. This is also true when additional measures are taken, such as working under a protective gas atmosphere.

It is particularly advantageous that, with electron beam heating, wires made of non-noble metals can also be used for producing bead single crystals.

Gas inclusions are fundamentally prevented in accordance with the invention. If it has any at all, the crystal has only minor dislocation densities, and in this manner an entirely new class of bead single crystals is provided. Thus, the selection of the wire material is advantageously no longer restricted to noble metals because oxidation of the metals is prevented in the vacuum.

In another embodiment of the invention, a high vacuum is applied during the method. It can be less than 5*10⁻⁴ mbar, in particular less than 10⁻⁶ mbar.

It is particularly advantageous that wires including Ag, Al, Cr, Cu, Ir, Mo, Nb, Ni, Pd, Pt, Re, Rh, Ru, Ta, Va, or W can be formed into bead single crystals. The wires can comprise these materials in a more or less pure form.

It is also possible to form bead single crystals from wires including metal alloys, in particular including Ag/Au, Pt/Rh, and Pt/Re alloys using electron beam heating in the vacuum.

In another particularly advantageous embodiment of the invention, electron beam heating is first applied for preventing gas inclusions and for forming a growth nucleus and then a flame melting method (FM or FFZ method) is applied. This is particularly advantageous when two or more wires made of two different materials are melted and recrystallized, e.g. for Pd/Va alloys or Cu/Ni alloys.

The invention will be explained in greater detail in the following using an exemplary embodiment and the enclosed drawing.

### BRIEF DESCRIPTION OF THE DRAWING

FIG. 1 depicts the device for electron beam heating in accordance with the invention.

### DETAILED DESCRIPTION OF THE INVENTION

The entire structure is disposed in a vacuum chamber that is made of noble steel 1 and that is pumped to a vacuum of ˜1×10⁻⁶ mbar using a turbomolecular pump (not shown).

An electron beam is generated by electrically heating a metal filament 2 e.g. made of tungsten or tantalum and having a diameter of approximately 0.2 to 0.3 mm. A direct voltage source 7 supplies the filament 2 with about 50 Watts of power.

Except for an upper aperture (not shown), the filament 2 is enclosed by a metal housing 3. This ensures that the light produced by the filament 2 is captured. The electron beam exits from the housing 3 via the aperture.

Arranged a few millimeters above the aperture in the housing 3 is a metal wire 4. It has a diameter of for instance 0.1 to 2 mm. The metal wire 4 can be displaced vertically relative to the filament 2 using an alignment device (not shown), and thus can be positioned above the aperture of the housing 3.

The electrons exiting from the housing 3 are accelerated to the metal wire 4 by means of a high voltage source 8 and by applying a positive high voltage to the metal wire 4, typically ranging from 2 to 3 kV. While electrons heat the metal wire 4, an emission current that is typically a few mA runs off via the wire 4. Due to the electron beam heating, in the first step the wire 4 is melted and a liquid metal ball or bead forms that is held to the wire 4 by the surface tension of the liquid metal.

The wire 4 is then moved vertically downward relative to the filament 2 and the wire 4 is further melted until the bead single crystal 5 has the desired size. Now the heat output of the electron beam heating is reduced until the upper part of the bead single crystal 5 hardens. The phase boundary between the solid and liquid phase of the bead single crystal 5 can be observed through a viewing window 6.

Precisely observing the hardening is above all for verifying the formation of a single crystal bead crystal. Observation of regularly arranged facets of low surface energy indicates the presence of such a bead single crystal 5.

A particular advantage of the electron beam heating is the simple and precise control of the phase limit by varying the high voltage used or the current through the filament 2. The bead single crystal 5 is produced by slow hardening of the liquid metal ball. If the melting and hardening processes are repeated frequently, the single crystal finally forms; it can be recognized by the formation of facets on the bead surface. The bead single crystals produced in this manner can have a diameter of about 0.5 to 3 millimeters.

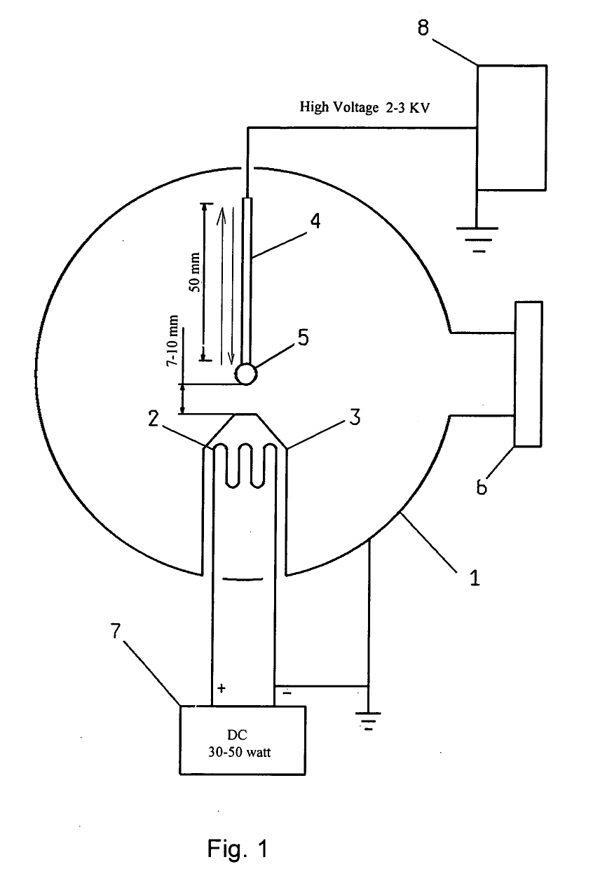

The high voltage and direct voltage values provided in the foregoing and the dimensions and distances (FIG. 1) are merely examples. Naturally one skilled in the art is free to set other values, depending on the wire (material) used for producing the bead single crystal. It is conceivable e.g. to melt and recrystallize in this manner a plurality of twisted wires that are made of non-noble metals, such as are known from DE 103 04 533.

The crystals are used for single crystal substrates in surface research, thin film technology, e.g. the structure of sensors, and in electrochemistry.

1.-18. (canceled)

19. A method for producing a bead single crystal, comprising:
forming said bead single crystal using electron beam heating of at least one wire.

20. A method according to claim 19, wherein said forming using said electron beam heating is performed in a high vacuum.

21. A method according to claim 19, wherein said forming using said electron beam heating is performed in a vacuum less than 5*10⁻⁴ mbar.

22. A method according to claim 19, wherein said forming using said electron beam heating is performed in a vacuum less than 10⁻⁶ mbar.

23. Method in accordance with claim 19, wherein:
said at least one wire comprises Ag, Al, Cr, Cu, Ir, Mo, Nb, Ni, Pd, Pt, Re, Rh, Ru, Ta, or W; and
said forming includes melting and recrystallizing said at least one wire.

24. A method according to claim 23, wherein the melting and recrystallizing said at least one wire is repeated multiple times.

25. A method according to claim 19, wherein at least one wire for producing metal alloys is selected

26. A method according to claim 25, wherein said at least one wire comprises one selected from the group consisting of Ag/Au, Pt/Pd, Pt/Rh, and Pt/Re alloys.

27. A method according to claim 19, further comprising producing a metal alloy from at least two wires by using a flame melting method additionally after said electron beam heating.

28. A method according to claim 19, wherein said at least one wire is heated to up to 3500° C.

29. A method according to claim 23, further comprising cleaning said at least one wire prior to the melting.

30. A method according to claim 29, wherein said cleaning includes at least one etching and/or at least one alcohol treatment prior to the melting.

31. A bead single crystal, produced in accordance with the method of claim 19.

32. A bead single crystal according to claim 31 which is free of gas inclusions.

33. A bead single crystal according to claim 31, comprising Ag, Al, Cr, Cu, Ir, Mo, Nb, Ni, Pd, Pt, Re, Rh, Ru, Ta, Va, and/or W.

34. A bead single crystal according to claim 31, comprising metal alloys.

35. A bead single crystal according to claim 34, wherein said metal alloys include one selected from the group consisting of Ag/Au, Pt/Pd, Pt/Rh, and Pt/Re alloys.

36. A bead single crystal according to claim 31, wherein said bead single crystal is cut off on a crystallographically oriented facet.

37. A bead single crystal according to claim 31, wherein said bead single crystal has a smooth surface.

38. A bead single crystal according to claim 31, wherein a diameter of said bead single crystal is about 0.5 to 3 millimeters.

39. A bead single crystal according to claim 31, wherein said bead single crystal is suited for use in surface research, thin film technology, sensors, or in electrochemistry.
